(19) United States
(12) Patent Application Publication
(10) Pub. No.: US 2019/0150293 A1
(43) Pub. Date: May 16, 2019

(54) ELECTRONIC DEVICE MODULE

(71) Applicant: LUXVISIONS INNOVATION TECHNOLOGY LIMITED (GUANGZHOU) CO., LTD., GUANGZHOU (CN)

(72) Inventor: JIANHUI CHEN, GUANGZHOU (CN)

(21) Appl. No.: 16/185,246

(22) Filed: Nov. 9, 2018

(30) Foreign Application Priority Data
Nov. 10, 2017 (CN) 201711105851.2

(51) Int. Cl. H05K 3/26; H05K 3/00

(52) U.S. Cl. CPC H05K 3/26; H05K 3/007; B08B 3/04; H05K 2203/1377; H05K 2203/0766; H05K 3/0055

(57) ABSTRACT

An electronic device module adapted to be removably attached by a heat-resistant tape includes a substrate, a waterproof enclosure and an electronic device. The substrate has a front surface and a rear surface that is opposite to the front surface. The waterproof enclosure is disposed on the rear surface of the substrate to form a closed path and is adapted to be attached by the heat-resistant tape so as to be interposed between the rear surface and the heat-resistant tape. The electronic device is formed on the front surface of the substrate.

### CROSS-REFERENCE TO RELATED APPLICATION

This application claims priority of Chinese Patent Application No. 201711105851.2, filed on Nov. 10, 2017.

### FIELD

The disclosure relates to an electronic device module, and more particularly to an electronic device module including a waterproof enclosure.

### BACKGROUND

A conventional chip on board manufacturing process is generally conducted by directly disposing an electronic device on a substrate, such as a copper substrate, electrically connecting electronic device and the copper substrate via wire bonding, and filling a plurality of through holes formed in a back surface of the copper substrate using an ink in a manner that the back surface is partly exposed for grounding. Thereafter, the copper substrate and the electronic device disposed thereon are subjected to subsequent packaging process to form an electronic device module for removing dirt or stains inside the electronic device module through water-rinsing process.

When the rinsing process is conducted, the entire back surface of the copper substrate is required to be covered by a heat-resistant tape in advance before being rinsed with water. However, the ink that fills the through holes present on the back surface of the copper substrate caused the back surface to be uneven. When the heat-resistant tape is applied to the back surface of the copper substrate, undesired gaps tend to be formed between the heat-resistant tape and the uneven back surface, which results in permeation of water into the back surface through the gaps. When a subsequent baking process is conducted after the rinsing process, the presence of the water between the heat-resistant tape and the uneven back surface will cause yellowing of a portion of the back surface that is exposed from the ink. Thus, the appearance quality of the electronic device module is affected.

### SUMMARY

Therefore, an object of the disclosure is to provide an electronic device module that can alleviate at least one of the drawbacks of the prior art.

According to the disclosure, the electronic device module is adapted to be removably attached by a heat-resistant tape and includes a substrate, a waterproof enclosure and an electronic device.

The substrate has a front surface and a rear surface that is opposite to the front surface.

The waterproof enclosure is disposed on the rear surface to form a closed path and is adapted to be attached by the heat-resistant tape so as to be interposed between the rear surface and the heat-resistant tape.

The electronic device is formed on the front surface of the substrate.

### BRIEF DESCRIPTION OF THE DRAWINGS

Other features and advantages of the disclosure will become apparent in the following detailed description of the embodiment with reference to the accompanying drawings, of which:

FIG. 1 is a perspective view illustrating an embodiment of an electronic device module according to the disclosure;

FIG. 2 is a bottom view of a waterproof enclosure of the embodiment;

FIG. 3 is a partially cross-sectional view of the waterproof enclosure of the embodiment and a heat-resistance tape;

FIG. 4 is a bottom view of another configuration of the waterproof enclosure of the embodiment; and

FIG. 5 is a bottom view of yet another configuration of the waterproof enclosure of the embodiment.

### DETAILED DESCRIPTION

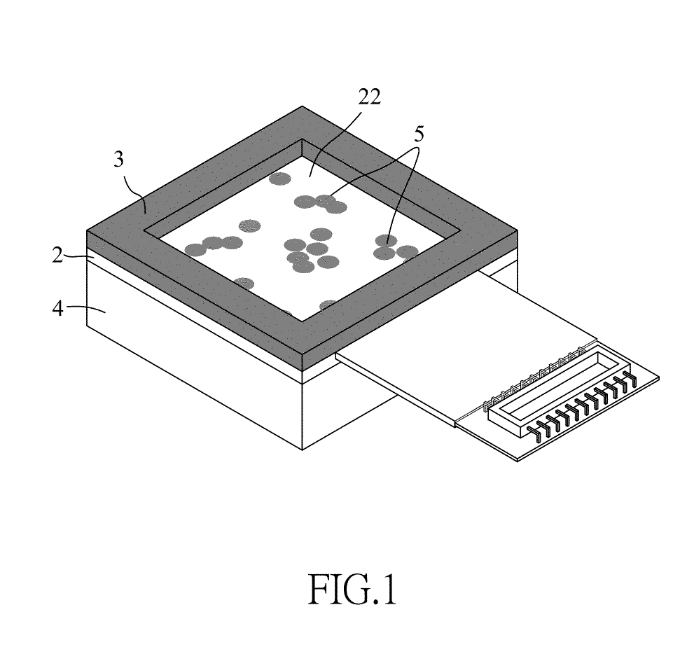

Referring to FIGS. 1 to 3, an embodiment of an electronic module according to the disclosure, which is removably attached by a heat-resistant tape 100, includes a substrate 2, a waterproof enclosure 3 that is disposed on the substrate 2, an electronic device 4 disposed on the substrate 2 opposite to the waterproof enclosure 3, and a plurality of fillers 5 that are formed on the substrate 2 and surrounded by the waterproof enclosure 3 in a spaced-apart manner.

To be specific, the substrate 2 has a front surface 21 and a rear surface 22 opposite to the front surface 21, and is formed with a plurality of spaced apart through holes 20 extending from the front surface 21 to the rear surface 22. The electronic device 4 is formed on the front surface 21 of the substrate 2. Each of the fillers 5 fills a respective one of the through holes 20 so as to avoid entering of dirt thereinto, which may lead to short circuit or other undesired results. The waterproof enclosure 3 is disposed on the rear surface 22 of the substrate 2 along a closed path such that a part of the rear surface 22 is exposed from and surrounded by the waterproof-enclosure 3. The heat-resistant tape 100 is attached to the waterproof enclosure 3 so that the waterproof enclosure 3 is interposed between the rear surface 22 of the substrate 2 and the heat-resistant tape 100.

It is noted that the substrate 2 may be a conventional circuit board such as an integrated circuit board, a rigid printed circuit board, a flexible printed circuit board, a rigid-flex circuit board, etc. Hence, after formation of the fillers 5 and the waterproof enclosure 3, the rear surface 22 of the substrate 2 is generally a copper surface, i.e., the exposed part of the rear surface 22 for subsequent process steps is composed of copper. In the embodiment, the waterproof enclosure 3 and the fillers 5 are made from ink that is commercially available. When the electronic device module is manufactured, the fillers 5 are filled in the through holes 20 prior to the deposition of the waterproof enclosure 3, so that during a subsequent rinsing process, water drops are prevented from leaking into the exposed part of the rear surface 22 of the substrate 2, which is surrounded by the waterproof enclosure 3. A non-limiting example of the electronic device 4 is a lens device. Since the electronic device 4 per se is not an essential feature of the disclosure, further details thereof are not provided herein for the sake of brevity.

More specifically, the electronic device module may be manufactured using chip on board (COB) techniques. That is to say, when the electronic device module of the disclosure is manufactured, after the electronic device 4 is disposed on the front surface 21 of the substrate 2 and is subjected to a wire bonding process, the through holes 20 are filled by the fillers 5 made of ink, and then the waterproof enclosure 3 is disposed on the rear surface 22 of the substrate 2.

To be specific, when the electronic device module is subjected to the subsequent rinsing process to remove dirt or contaminants thereon, the heat-resistant tape 100 is attached to the rear surface 22 of the substrate 2 through the waterproof enclosure 3. Therefore, by means of the waterproof enclosure 3, the heat-resistant tape 100 is evenly and fluid-tightly attached to the rear surface 22 of the substrate 2, and water will not leak into the exposed part of the rear surface 22 that is surrounded by the waterproof enclosure 3 during the rinsing process, and yellowing of the exposed part of the rear surface 22 during a subsequent baking process can be avoided. It is worth noting that, the waterproof enclosure 3 is not limited in its application to the electronic device module manufactured using the COB techniques, and can be applied to any device modules as long as fabrication of such device modules involves the use of the heat-resistant tape and the rinsing and baking processes so as to avoid yellowing of the exposed surface of the substrate due to the rinsing and baking processes.

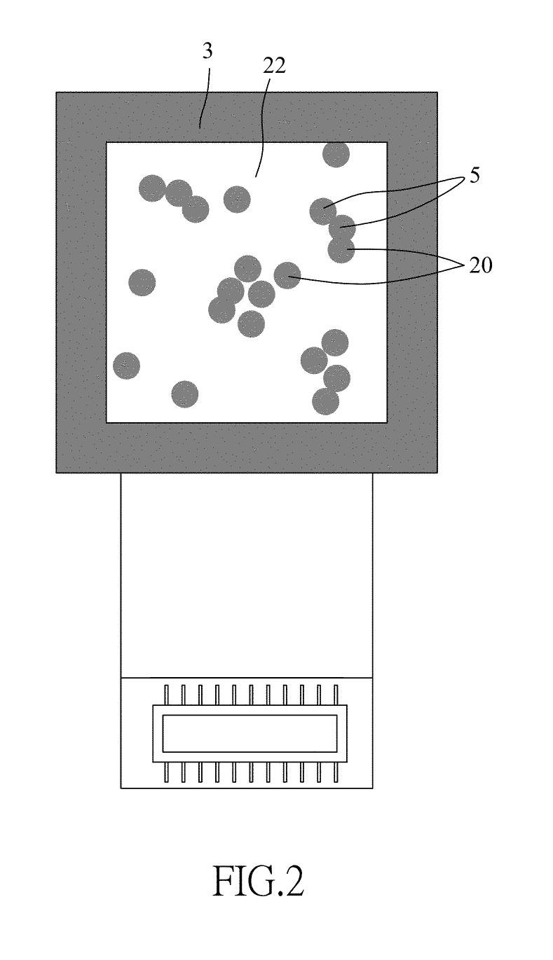

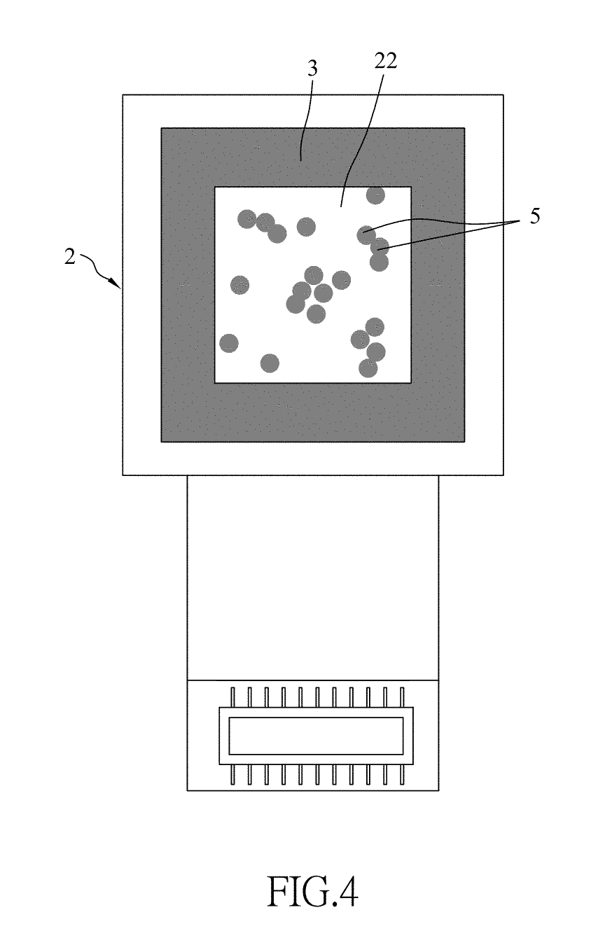

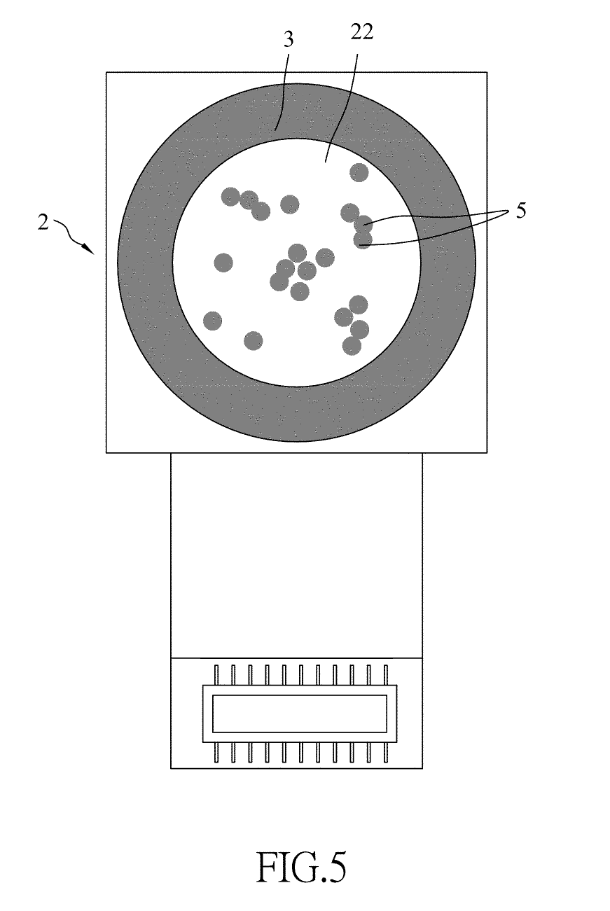

More specifically, referring to FIGS. 4 and 5, since the waterproof enclosure 3 is used for permitting even attachment of the heat-resistant tape 100 to the rear surface 22 of the substrate 2, the waterproof enclosure 3 is not required to form a particular shape when disposed on the rear surface 22 of the substrate 2 as long as a closed path can be formed. In other words, the shape of the closed path is not restricted and can be a shape selected from one of a hollow rectangle (as shown in FIGS. 2 and 4), a hollow square, a ring (as shown in FIG. 5), and other irregular hollow geometries.

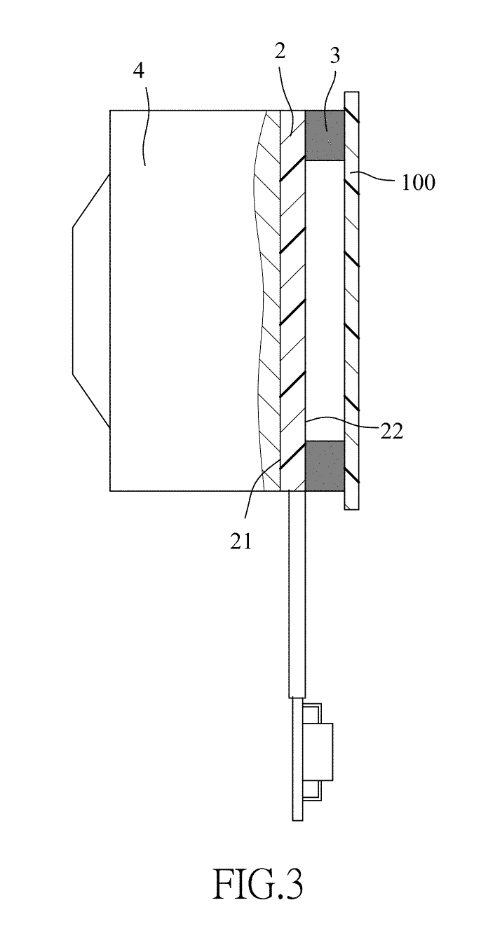

In addition, the position of the rear surface 22 of the substrate 2 on which the waterproof enclosure 3 is disposed thereon, is not limited as long as the heat-resistant tape 100 can be evenly and fluid-tightly attached to the rear surface 22 of the substrate 2 through the waterproof enclosure 3. Referring back to FIG. 3, the closed path may extend along a periphery of the rear surface 22 of the substrate 2. Alternatively, referring to FIGS. 4 and 5, the closed path is surrounded by and spaced apart from a periphery of the rear surface 22 of the substrate 2, and corresponds in shape to the periphery of the rear surface 22.

In the embodiment, the fillers 5 have a height protruding from the rear surface 22 of the substrate 2 not greater than a thickness of the waterproof enclosure 3. The unevenness of the rear surface of the substrate encountered by the conventional electronic device module due to protruding of the fillers from the rear surface can be eliminated to prevent water drops from permeating into the gaps between the heat-resistant tape and the uneven rear surface of the substrate.

To sum up, by virtue of the inclusion of the waterproof enclosure 3 that is disposed on the rear surface 22 of the substrate 2, the heat-resistant tape 100 can be evenly and fluid-tightly attached to the rear surface 22 of the substrate 2 through the waterproof enclosure 3. Specifically, when the waterproof enclosure 3 is disposed on the rear surface 22 of the substrate 2 to form the closed path as shown in FIG. 3, the water drops will not permeate into the region surrounded by the waterproof enclosure 3, and hence the exposed part of the rear surface 22 will not turn yellowish easily during the subsequent baking process. When the waterproof enclosure 3 is disposed on the rear surface 22 of the substrate 2 to form the closed path as show in FIGS. 4 and 5, the water drops will not permeate into the region that is surrounded by the waterproof enclosure 3 during the rinsing process, and any water drops that remained on a part of the rear surface 22 outside the area surrounded by the waterproof enclosure 3 after the rinsing process will be evaporated during the subsequent baking process. Therefore, the entire rear surface 22 of the surface 2 does not turn yellowish after the backing process.

In the description above, for the purposes of explanation, numerous specific details have been set forth in order to provide a thorough understanding of the embodiment. It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. An electronic device module adapted to be removably attached by a heat-resistant tape (100), comprising:
a substrate having a front surface and a rear surface that is opposite to said front surface;
a waterproof enclosure disposed on said rear surface to form a closed path and adapted to be attached by the heat-resistant tape so as to be interposed between said rear surface and said heat-resistant tape; and
an electronic device formed on said front surface of said substrate.

2. The electronic device module of claim 1, wherein said closed path has a shape selected from one of a hollow rectangle, a hollow square, a ring, and other irregular hollow geometries.

3. The electronic device module of claim 1, wherein said substrate is formed with a plurality of spaced-apart through holes, said electronic device module further comprising a plurality of fillers, each of said fillers filling a respective one of said through holes and having a height protruding from said rear surface not greater than a thickness of said waterproof enclosure.

4. The electronic device module of claim 3, wherein said waterproof enclosure surrounds said fillers in a spaced-apart manner.

5. The electronic device module of claim 3, wherein said fillers and said waterproof enclosure are made from ink.

6. The electronic device module of claim 1, wherein said closed path extends along a periphery of said rear surface of said substrate.

7. The electronic device module of claim 1, wherein said closed path is surrounded by and spaced apart from a periphery of said rear surface of said substrate, and corresponds in shape to said periphery of said rear surface.
